(19) United States
(12) Patent Application Publication
(10) Pub. No.: US 2019/0073917 A1
(43) Pub. Date: Mar. 7, 2019

(54) Virtual Reality Assisted Training

(71) Applicant: Motorola Mobility LLC, Chicago, IL (US)

(72) Inventors: Scott DeBates, Crystal Lake, IL (US); Douglas Lautner, Round Lake, IL (US)

(73) Assignee: Motorola Mobility LLC, Chicago, IL (US)

(21) Appl. No.: 15/698,280

(22) Filed: Sep. 7, 2017

(51) Int. Cl. G09B 9/00; G09B 19/00; H04N 13/04; G02B 27/01; B81B 7/00; B81B 7/04

(52) U.S. Cl. CPC G09B 9/00; G09B 19/003; H04N 13/044; G02B 2027/0134; B81B 7/0087; B81B 7/04; G02B 2027/0138; G02B 27/0172

(57) ABSTRACT

Systems and methods for virtual reality (VR) assisted training through simulation of an activity session entail recording the activity session by applying a recording array to a first subject. The recording array may have multiple motion sensors and a camera. Motion data and video data registered with the motion data are gathered during the activity session, and are stored as a session. The recorded session may be later replayed to the same user or a different user via a playback array on the subject. The playback array may include a video screen and one or more electromuscular stimulators, whereby the video data is replayed through the display screen and the motion data is replayed via the one or more electromuscular stimulators.

### TECHNICAL FIELD

The present disclosure is related generally to virtual reality (VR) and, more particularly, to systems and methods for enhancing VR-assisted training.

### BACKGROUND

VR technology allows users to experience a more immersive environment when playing games, training, and performing other simulated activities. VR headsets worn by users provide visual stimulation, such as via one or more embedded display units, and may also provide audio stimulation. As noted above, one of the growing uses of VR is for physical training simulation. While actual rather than simulated experiences will always be slightly superior, many people are interested in extreme physical experiences such as skiing, biking, marathon, Ironman, tour de France, etc., but lack the money, time, or risk tolerance to participate.

Before proceeding to the remainder of this disclosure, it should be appreciated that the disclosure may address some of the shortcomings listed or implicit in this Background section. However, any such benefit is not a limitation on the scope of the disclosed principles, or of the attached claims, except to the extent expressly noted in the claims.

Additionally, the discussion of technology in this Background section is reflective of the inventors' own observations, considerations, and thoughts, and is in no way intended to be, to accurately catalog, or to comprehensively summarize any prior art reference or practice. As such, the inventors expressly disclaim this section as admitted or assumed prior art. Moreover, the identification or implication herein of one or more desirable courses of action reflects the inventors' own observations and ideas, and should not be assumed to indicate an art-recognized desirability.

### BRIEF DESCRIPTION OF THE SEVERAL VIEWS OF THE DRAWINGS

While the appended claims set forth the features of the present techniques with particularity, these techniques, together with their objects and advantages, may be best understood from the following detailed description taken in conjunction with the accompanying drawings of which:

FIG. 1 is a modular view of an example electronic device usable in implementation of one or more embodiments of the disclosed principles;

FIG. 2 is a modular schematic of an example VR headset in accordance with an embodiment of the described principles;

FIG. 3 is a schematic view of a recording array sensor system in accordance with an embodiment of the described principles;

FIG. 4 is a schematic view of the back of the recording array sensor system of FIG. 3 in accordance with an embodiment of the described principles;

FIG. 5 is a flow chart showing a process of activity session recordation in accordance with an embodiment of the described principles;

FIG. 6 is a schematic diagram of a playback array in accordance with an embodiment of the described principles; and

FIG. 7 is a flow chart showing a process by which an activity session may be replayed to a user wearing a playback array such as the array shown in FIG. 6.

### DETAILED DESCRIPTION

Before presenting a detailed discussion of embodiments of the disclosed principles, an overview of certain embodiments is given to aid the reader in understanding the later discussion. As noted above, one of the growing uses of VR is for physical training simulation. For example, a user may exercise via simulate participation in extreme physical experiences such as skiing, biking, marathon, Ironman, tour de France, etc. In an embodiment if the described principles, training via VR allows the exercise load to be adapted to match the user's physical capabilities through monitoring of the user's vital parameters and analyzing the user's exercise data history. In a further embodiment, an instrumented suit or sensor harness is worn by the user and allows the system to detect or determine user biological parameters during exercise. Moreover, in an embodiment, the user's historical performance is stored and accessed to evaluate or facilitate a current exercise session.

With this overview in mind, and turning now to a more detailed discussion in conjunction with the attached figures, the techniques of the present disclosure are illustrated as being implemented in or via a suitable device environment. The following device description is based on embodiments and examples within which or via which the disclosed principles may be implemented, and should not be taken as limiting the claims with regard to alternative embodiments that are not explicitly described herein.

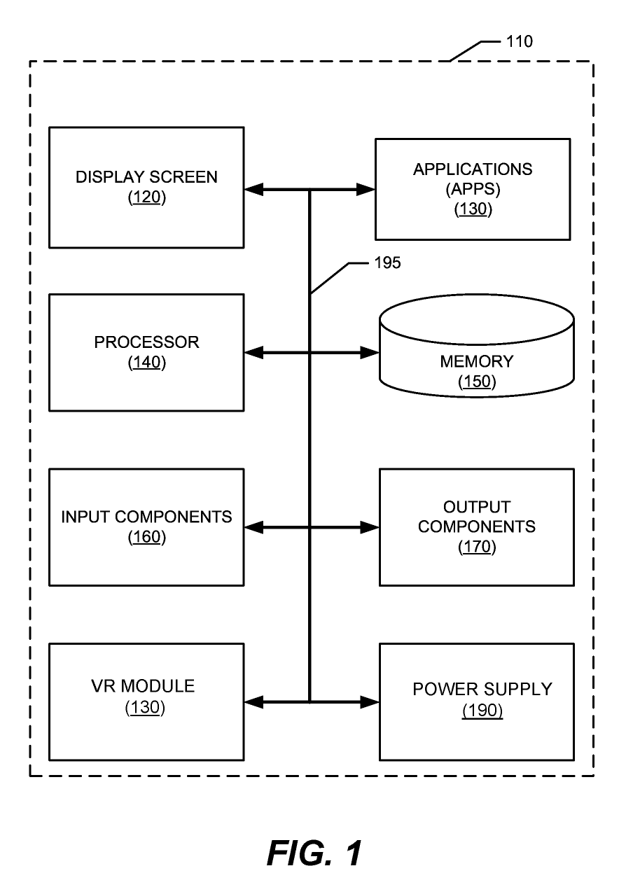

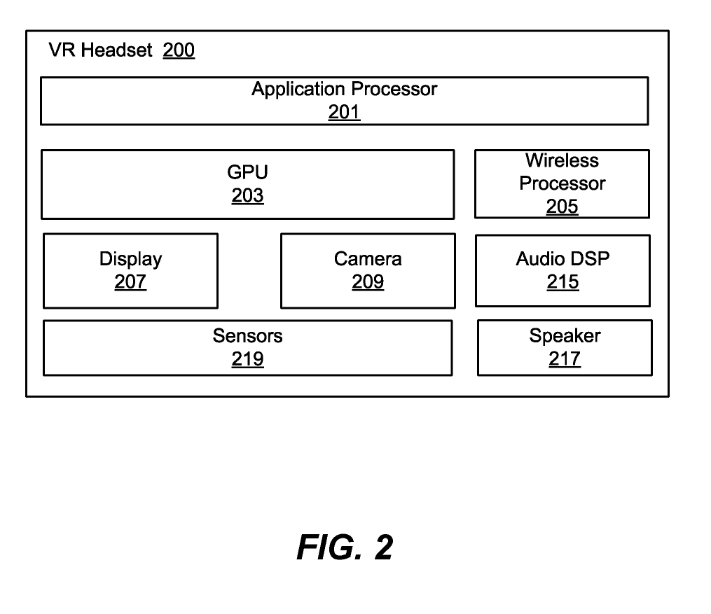

Thus, for example, while FIG. 1 illustrates an example computing device with respect to which embodiments of the disclosed principles may be implemented, it will be appreciated that other device types may be used, including but not limited to laptop computers, tablet computers, and so on. Moreover, FIG. 2 will be used to describe a further computing device in the form of a VR headset, which may be used to implement various of the disclosed embodiments.

The schematic diagram of FIG. 1 shows an exemplary mobile device 110 forming part of an environment within which aspects of the present disclosure may be implemented. In particular, the schematic diagram illustrates a user device 110 including example components. It will be appreciated that additional or alternative components may be used in a given implementation depending upon user preference, component availability, price point and other considerations.

In the illustrated embodiment, the components of the user device 110 include a display screen 120, applications (e.g., programs) 130, a processor 140, a memory 150, one or more input components 160 such as RF input facilities or wired input facilities, including, for example one or more antennas and associated circuitry and logic. The antennas and associated circuitry may support any number of protocols, e.g., WiFi, Bluetooth, cellular, etc.

The device 110 as illustrated also includes one or more output components 170 such as RF (radio frequency) or wired output facilities. The RF output facilities may similarly support any number of protocols, e.g., WiFi, Bluetooth, cellular, etc. and may be the same as or overlapping with the associated input facilities. It will be appreciated that a single physical input may serve for both transmission and receipt.

The processor 140 can be any of a microprocessor, microcomputer, application-specific integrated circuit, or the like. For example, the processor 140 can be implemented by one or more microprocessors or controllers from any desired family or manufacturer. Similarly, the memory 150 is a nontransitory media that may reside on the same integrated circuit as the processor 140. Additionally or alternatively, the memory 150 may be accessed via a network, e.g., via cloud-based storage. The memory 150 may include a random access memory (i.e., Synchronous Dynamic Random Access Memory (SDRAM), Dynamic Random Access Memory (DRAM), RAMBUS Dynamic Random Access Memory (RDRM) or any other type of random access memory device or system). Additionally or alternatively, the memory 150 may include a read-only memory (i.e., a hard drive, flash memory or any other desired type of memory device).

The information that is stored by the memory 150 can include program code associated with one or more operating systems or applications as well as informational data, e.g., program parameters, process data, etc. The operating system and applications are typically implemented via executable instructions stored in a non-transitory computer readable medium (e.g., memory 150) to control basic functions of the electronic device 110. Such functions may include, for example, interaction among various internal components and storage and retrieval of applications and data to and from the memory 150.

Further with respect to the applications and modules such as a VR module 180, these typically utilize the operating system to provide more specific functionality, such as file system service and handling of protected and unprotected data stored in the memory 150. The VR module 180 is a software agent in an embodiment that manages the device 110's operations and interactions with respect to a VR headset. The VR headset will be shown in more detail later herein.

With respect to informational data, e.g., program parameters and process data, this non-executable information can be referenced, manipulated, or written by the operating system or an application. Such informational data can include, for example, data that are preprogrammed into the device during manufacture, data that are created by the device or added by the user, or any of a variety of types of information that are uploaded to, downloaded from, or otherwise accessed at servers or other devices with which the device is in communication during its ongoing operation.

In an embodiment, a power supply 190, such as a battery or fuel cell, is included for providing power to the device 110 and its components. Additionally or alternatively, the device 110 may be externally powered, e.g., by a vehicle battery or other power source. In the illustrated example, all or some of the internal components communicate with one another by way of one or more shared or dedicated internal communication links 195, such as an internal bus.

In an embodiment, the device 110 is programmed such that the processor 140 and memory 150 interact with the other components of the device 110 to perform a variety of functions. The processor 140 may include or implement various modules (e.g., the VR module 180) and execute programs for initiating different activities such as launching an application, transferring data and toggling through various graphical user interface objects (e.g., toggling through various display icons that are linked to executable applications). As noted above, the device 110 may include one or more display screens 120. These may include one or both of an integrated display and an external display.

FIG. 2 shows the architecture of an example VR headset 200 in accordance with an embodiment of the described principles. In the illustrated embodiment, the VR headset 200 interacts with the user through a display 207 and a speaker 217. Additional elements include a graphics processing unit (GPU) 203, for advanced graphics generation and processing, as well as an audio digital signal processor (DSP) 215 for sound decoding and playback. A camera 209 associated with the VR headset 200 allows the headset 200 to collect visual data regarding the physical surroundings during use of the headset 200. Furthermore, a sensor set 219 is included to provide motion sensors for image stabilization, velocity (based on running, biking, etc.), and other uses.

The VR headset 200 includes a wireless processor 205 in the illustrated embodiment to connect the headset 200 to one or more other data sources or sinks, such as a game console, another headset, a mobile phone, etc. Finally, an application processor 201 executes the primary processes of the headset 200 by controlling the aforementioned components. Thus, for example, the application processor 201 may sample and respond to the thermalpile sensors 211, control the camera 209 and wireless processor 205, and execute the steps described herein.

It will be appreciated that the application processor 201 operates by reading computer-executable instructions from a nontransitory computer-readable medium and subsequently executing those instructions. The nontransitory computer-readable medium may include any or all of, or alternatives of, random access memory (i.e., Synchronous Dynamic Random Access Memory (SDRAM), Dynamic Random Access Memory (DRAM), RAMBUS Dynamic Random Access Memory (RDRM) or any other type of random access memory device or system) and read-only memory (i.e., a hard drive, flash memory or any other desired type of read-only memory device).

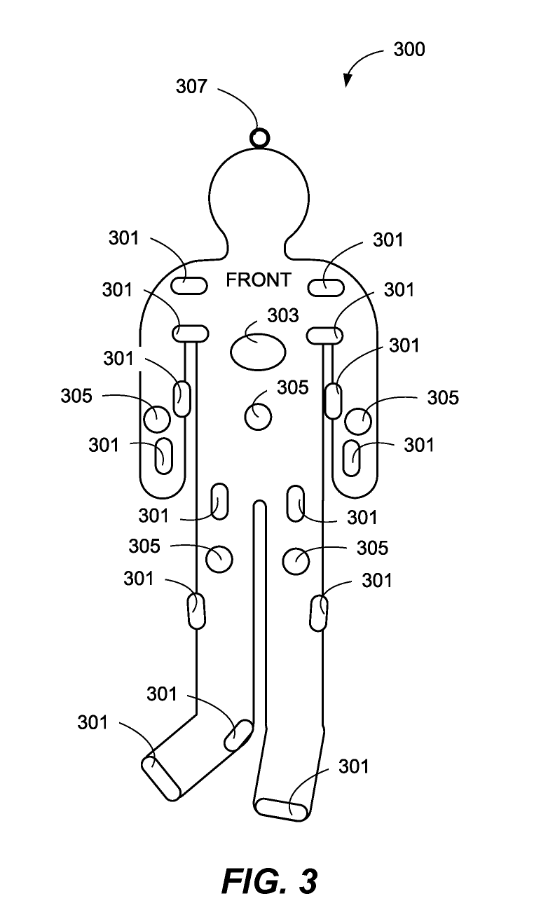

Turning to FIG. 3, this figure shows a schematic view of a sensor system, or “recording array,” in keeping with an embodiment of the described principles. The illustrated system 300 includes a number of components that may exist as a collection of loose pieces or as portions of a suit or harness. Thus, for example, the system 300 may be donned by the user either by applying each element or by applying one or more groups of elements.

The illustrated embodiment of the system 300 includes MEM (micro-electrical-mechanical) sensors 301 placed in proximity to various bending joints to capture the motion of those joints. In the figure, the MEM sensors 301 are located above and below each shoulder, at each elbow, at each wrist, at each hip, at each knee, at each ankle or sole, and across each set of toes.

In addition, a heart sensor 303 such as an EKG sensor may be used to measure and track the user's heart rate. Temperature sensors 305 may be distributed within the system 300 to measure the ambient temperature at the user's physical location. As the ambient temperature will generally be measured in air which conveys temperature convectively, the plurality of temperature sensors 305 allows the system 300 to provide a reasonable measurement of the spatially average temperature at the user's location.

A 360° video camera 307 is employed as part of the system 300 in accordance with an embodiment. This camera 307 may be a part of a VR headset (not shown) worn by the user or may be mounted as part of the system 300. In an embodiment, the video camera 307 may also record audio data.

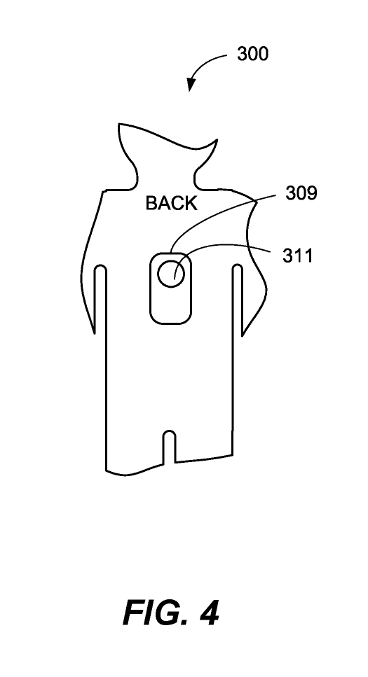

The back of the system 300, shown in FIG. 4, includes a hub module 309, which in an embodiment is the central location for receiving and processing all sensor data, location data, and video data. This data may be processed, stored, and wirelessly transmitted from the system 300 to another location or device such as a personal mobile device, e.g., a cellular phone. The hub module 309 includes, for example, a CPU, a memory, a modem, and sensor inputs. A GPS sensor 311 may be used as well, in order to track the user's core location, e.g., for sensor calibration or drift correction.

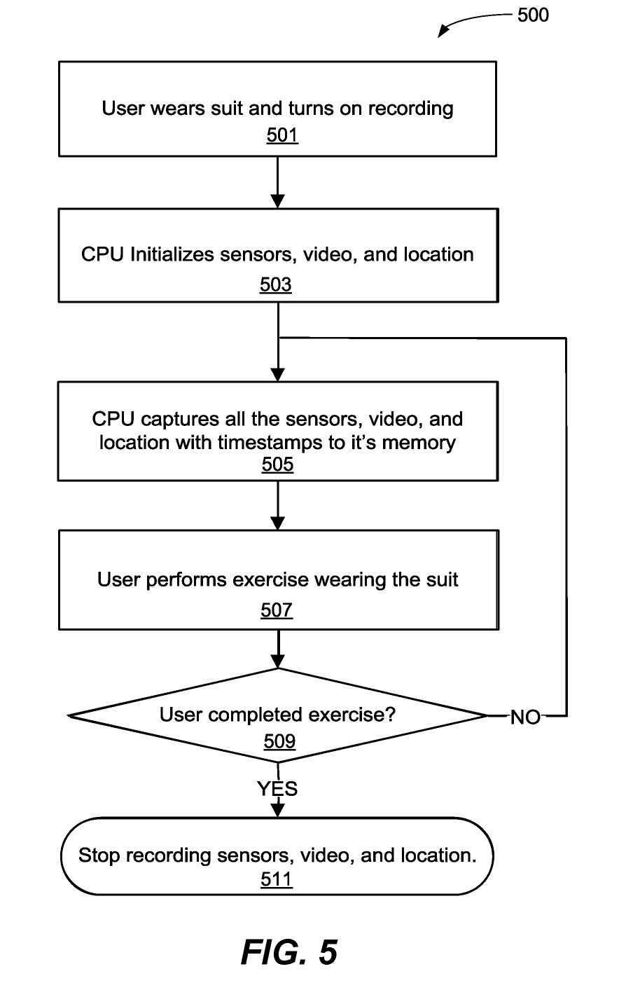

In use, the system 300 allows the user to perform an activity such as, but not limited to, exercise, e.g., in a VR setting, while recording an tracking user vital parameters for contemporaneous use, e.g., by changing resistance parameters, or for later analysis. Other activities such as entertainment or leisure activities may also be simulated using the disclosed principles. The flow chart of FIG. 5 shows an overview of a process 500 executed in the context of the sensor system 300 described above. At stage 501 of the process 500, the user dons the system 300 and powers on the electronic components of the system, e.g., the sensor hub 309, GPS 311, MEM sensors 301, heart sensor 303, temperature sensors 305 and camera 307. The system 300 may be powered on in conjunction with a separate VR headset if used.

At stage 503 of the process 300, the CPU of the sensor hub 309 initializes the sensors, camera and GPS elements. This step may include sensor checks and calibration, location initialization and so on. The CPU of the sensor hub 309 then captures (receives or samples) data from the identified inputs, e.g., the sensors, camera and GPS at stage 505 and stores the data in time-stamped format. The timestamp may be made part of the data or may be via an external reference such as order, memory location, etc.

The user exercises while wearing the system 300, an activity represented as stage 507 of process 500. Although stage 507 is shown sequentially after stage 505, it will be appreciated that the user may begin movement before powering the system 300 on, or powering the system 300 on but before initialization has occurred. While the user is exercising, the process of gathering data continues.

To this end, at stage 509 of the process 300, the CPU periodically determines whether the user is still exercising. This determination may be made in any number of ways, but in an embodiment, the CPU determines whether the user is exercising by noting regular strenuous movement of the body, e.g., via the sensors 305. The degree if movement needed to determine that a user is exercising may be determined by reference to periods, such as at start up, when the user may not have been exercising. In other words, if the user exhibits a continuous pattern of movement that differs substantially from their resting pattern, then this pattern is a likely an exercise pattern. Other parameters such as heart rate may also be used additionally or alternatively to determine if the user is exercising.

If the it is determined at stage 509 that the user is still exercising, then the process 500 returns to stage 505, whereupon the CPU collects the indicated data and continues with subsequent steps. If instead it is determined at stage 509 that the user is no longer exercising, then the process 500 flows to stage 511, whereupon the CPU stops the recording of sensor and video data. This cessation may be accompanied by other actions relative to the data just recorded, e.g., analysis, compression, encoding, transmission, and so on.

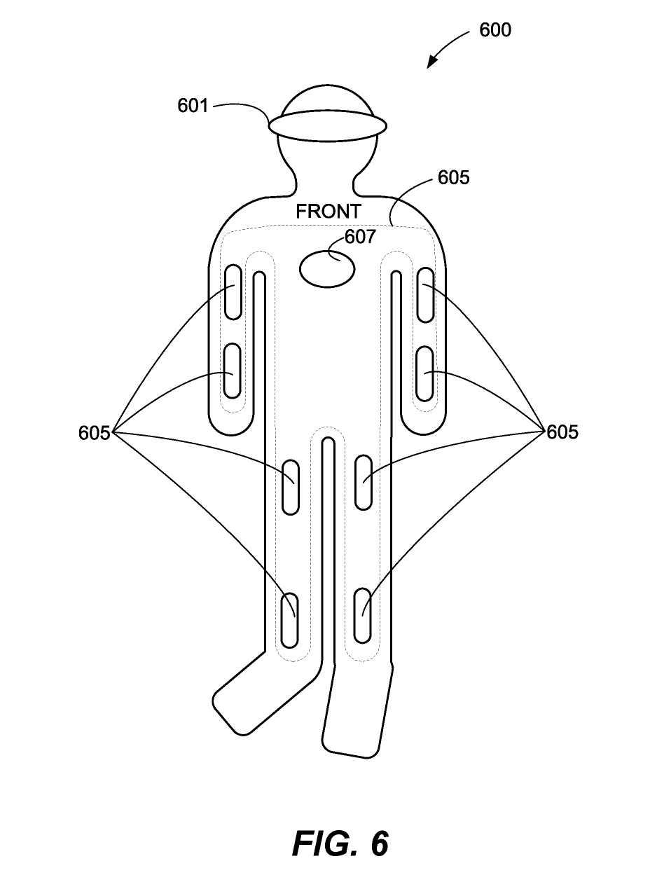

A user may experience VR playback of an exercise session, whether their own or someone else's, by wearing a playback array such as the VR suit 600 as schematically shown in FIG. 6. The VR suit 600 includes primarily a VR headset 601, a number of electromuscular stimulators 603 and associated wiring, a heating/cooling system 605 and an EKG 607 to monitor the user's heart rate during playback. The electromuscular stimulators 603 elicit muscle contraction using electric impulses. The impulses may be applied via adhesive electrodes placed on the skin over the muscles of interest.

During playback, the VR headset 601 plays 360° video captured by the camera 307 during the exercise session of interest, and also plays any available captured audio data. Similarly, the electromuscular stimulators 603 selectively contract the user's muscles during playback in synch with the camera playback to simulate the movements captured by the sensors 301 during the exercise session.

Finally, the heating/cooling system 605 is activated to replicate the temperatures measured by the temperature sensors 305 during the exercise session. For example, if the user walked in cold water during the original exercise session, then during playback, the heating/cooling system 605 will chill the user's lower legs to the appropriate temperature. The heating/cooling system 605 may be a thermoelectric system, a water-based system, an air-based system, or other suitable heating/cooling structure.

As with the recording system 300, the back of the VR suit 600 may contain a central module 607 from which all sensor data, and video are processed. Again, the central module may comprise a CPU, memory, modem, sensor inputs and actuator outputs. The actuator outputs in an embodiment include a temperature command output, a muscle stimulation activation output and audio/video outputs.

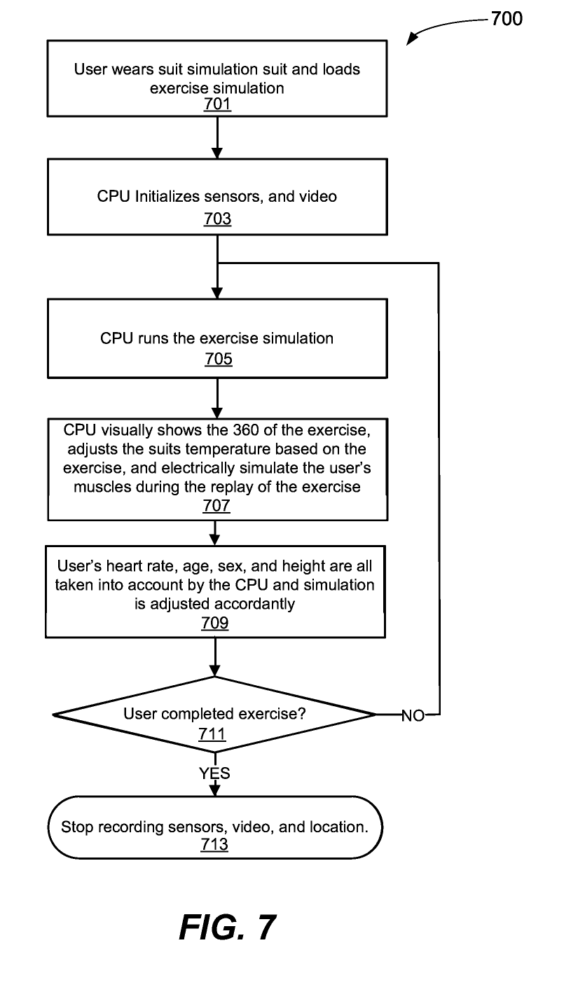

FIG. 7 shows a process 700 by which an exercise session may be replayed to a user wearing a VR suit such as the suit 600 shown in FIG. 6. At stage 701 of the process 700, the user dons VR suit and loads the exercise simulation of interest (e.g., a session recorded in the manner described herein). The CPU then initializes sensors and audio/video at stage 703 and runs the exercise simulation at stage 705.

At stage 707, while running the simulation, the CPU replays the audio and video recording of the session, adjusts the suit's temperature based on the temperatures recorded during the session, and electrically simulate the user's muscles to replicate the movements of the body. As discussed above, stimulation of the user's muscles to replicate movements made during the initial recording allow the replaying user to experience a similar exercise as the original actor.

However, different replay users may have a different physiques, and so using a single power level for muscle stimulation across all users may lead to overstimulation in some users and under-stimulation in others. In an embodiment of the disclosed principles, the amount of electrical power provided to contract a muscle during replay is based on the user's size (e.g., height and weight), and on additional optional factors such as age, heart rate and so on. In a further embodiment, the user provides the information needed to set the stimulation power during a configuration step prior to running the simulation. Examples of input parameters include sex, age, body type (small, medium, large, x-large), height, weight, age etc.

The power, range or speed of stimulation may also be adjusted in real time during the simulation. In an embodiment, the user's heart rate, age, sex, and height are taken into account by the CPU for the simulation at stage 709 and the simulation may be adjusted accordingly. For example, if the user's heart rate is excessive during replay, the CPU may adjust the replay to proceed at a lower rate or may decrease the range of stimulated movement.

At stage 711, the CPU determines whether the session is complete, e.g., by determining whether there is more of the recorded session yet to play. If it is determined at stage 711 that the session is not complete, then the process returns to stage 705 and executes that stage and subsequent steps. Otherwise, if it is determined at stage 711 that the session is complete, the process 700 flows to stage 713, whereupon the replay is stopped, as is all sensor sampling. In an alternative embodiment, the user may voluntarily terminate the session early. Early termination can allow the user to turn their attention to an emergent task or to rest if the user is feeling ill or winded.

In an embodiment, the CPU of the playback system 600 presents the user with a choice of sessions to experience. The sessions may be the user's own sessions or the sessions of one or more third parties. In an embodiment, the user is permitted to choose from among all of these sources. In a further embodiment, the user is prompted to choose a session intensity prior to or during a session. The session can then be adjusted in intensity as described above, e.g., by slowing the playback or moderating the range of movement.

Although the examples herein employ a VR headset for playback, and although playback via a VR headset tends to improve user immersion, it will be appreciated that simple video or simulated video may be used rather than 360° video. In general, it will be appreciated that while the described techniques are especially useful within VR environments, the same principles may be applied equally in non-VR environments.

It will be appreciated that various systems and processes for exercise session recording and simulation have been disclosed herein. However, in view of the many possible embodiments to which the principles of the present disclosure may be applied, it should be recognized that the embodiments described herein with respect to the drawing figures are meant to be illustrative only and should not be taken as limiting the scope of the claims. Therefore, the techniques as described herein contemplate all such embodiments as may come within the scope of the following claims and equivalents thereof.

We claim:

1. A method of virtual reality assisted training through simulation of an activity session comprising:
recording the activity session by applying a recording array having plurality of motion sensors and a camera to a first subject, and gathering motion data and video data registered with the motion data during the activity session, and storing the recorded data as a session; and
replaying the recorded session to a second subject via a playback array on the second subject including a video screen and one or more electromuscular stimulators, whereby the video data is replayed through the display screen and the motion data is replayed via the one or more electromuscular stimulators.

2. The method in accordance with claim 1, wherein the plurality of motion sensors comprise micro-electrical-mechanical (MEM) sensors.

3. The method in accordance with claim 2, wherein two or more of the MEM sensors are arranged in pairs around subject joints in the recording array.

4. The method in accordance with claim 1, wherein the recording array further comprises a location sensor and wherein gathering motion data and video data registered with the motion data further comprises gathering location data with the location sensor, the location data being registered with the motion data.

5. The method in accordance with claim 4, wherein the location sensor includes a global positioning satellite (GPS) receiver.

6. The method in accordance with claim 1, wherein the recording array further comprises one or more ambient temperature sensors and the playback array further includes one or more temperature sources, and wherein gathering motion data further comprises gathering temperature data with the one or more ambient temperature sensors, the temperature data being registered with the motion data, and wherein replaying the recorded session to the second subject includes replaying the temperature data in registration with the motion data via the one or more temperature sources.

7. The method in accordance with claim 1, wherein the camera further includes a microphone for gathering ambient audio data, and wherein gathering video data further comprises gathering audio data with the microphone, the audio data being registered with the video data, and wherein replaying the recorded session to the second subject includes replaying the audio data in registration with the video data.

8. The method in accordance with claim 1, wherein the first subject and the second subject are the same individual.

9. The method in accordance with claim 1, wherein the playback array includes a virtual reality (VR) headset of which the video screen is a part, and wherein replaying the recorded session comprises replaying the video data via the VR headset.

10. A system for simulating an activity session comprising:
a recording array including a plurality of motion sensors and a camera configured to be donned by a first subject, the recording array being further configured to gather motion data and video data registered with the motion data during the activity session by the first subject, and storing the recorded data as a session; and
a playback array configured to be donned by a second subject, the playback array including a video screen and one or more electromuscular stimulators, the playback array being further configured to replay the video data through the display screen in coordination with replaying the motion data via the one or more electromuscular stimulators.

11. The system in accordance with claim 10, wherein the plurality of motion sensors comprise micro-electrical-mechanical (MEM) sensors.

12. The system in accordance with claim 11, wherein two or more of the MEM sensors are arranged in pairs around subject joints in the recording array.

13. The system in accordance with claim 10, wherein the recording array further comprises a location sensor providing location data registered with the motion data.

14. The system in accordance with claim 13, wherein the location sensor includes a global positioning satellite (GPS) receiver.

15. The system in accordance with claim 10, wherein the recording array further comprises one or more ambient temperature sensors and the playback array further includes one or more temperature sources, and wherein the playback array is further configured to replay the temperature data in registration with the motion data via the one or more temperature sources.

16. The system in accordance with claim 10, wherein the camera further includes a microphone for gathering ambient audio data, and wherein the playback array includes one or more speakers for replaying the audio data in registration with the video data.

17. The system in accordance with claim 10, wherein the playback array includes a virtual reality (VR) headset of which the video screen is a part.

18. A method of simulating an activity session comprising:
recording an activity session executed by a first user by recording user movements during the session in registration with recording ambient visual conditions during the session; and
replaying the activity session to a second user by replaying the recorded movements via one or more electromuscular stimulators while also replaying the recorded visual conditions in registration with the replayed recorded movements.

19. The method in accordance with claim 18, wherein the first user and the second user are the same individual.

20. The method in accordance with claim 18, wherein replaying the activity session to the second user further comprises modifying a characteristic of the recorded movements prior to replaying the movements.
